(19) United States
(12) Patent Application Publication
(10) Pub. No.: US 2025/0305184 A1
(43) Pub. Date: Oct. 2, 2025

(54) SAPPHIRE PELLET FEED SYSTEM FOR THE GROWTH OF SAPPHIRE CRYSTALS AND METHOD THEREOF

(71) Applicant: John Outwater, Bedford, MA (US)

(72) Inventor: John Outwater, Bedford, MA (US)

(21) Appl. No.: 18/969,540

(22) Filed: Dec. 5, 2024

Related U.S. Application Data
(60) Provisional application No. 63/606,264, filed on Dec. 5, 2023.

(51) Int. Cl. C30B 35/00; G01G 13/02

(52) U.S. Cl. CPC C30B 35/005; G01G 13/026

(57) ABSTRACT

The present disclosure teaches a feed system for growing crystals, and the method thereof. The presently disclosed system includes a feeder suspended from a load cell. The feeder houses a hopper, for holding feed pellets, and a vibrator, for dispensing the feed pellets. The vibrator controls a rate of dispensing the feed pellets. The load cell measures a weight of the feeder and sends the measurement to a feedback controller in real-time. The feedback controller adjusts an operation of the vibrator based on the weight of the feeder. A Y-connector connects to a bottom of the feeder to divide the pellets into two equal streams. Each branch of the Y-connector connects to a flexible feed tube, which has two layers of walls, defining an interstice for hydrogen to flow through, protecting the feed pellets from moisture and air.

### TECHNICAL FIELD

The present disclosure generally relates to material science and chemical engineering.

### BACKGROUND

The presently disclosed technology teaches a method and system for providing a steady and even flow of sapphire pellet feed to a crucible for growing high-quality sapphire crystals. State-of-the-art technologies either result in imprecise and/or uneven crystal growth or are highly complex. Therefore, it would be beneficial to develop a highly precise feed system that is reliable and effective, as well as being relatively simple and easy to implement.

### SUMMARY

Generally, the present disclosure concerns a feed system to convey pellets of sapphire feed from a hopper to a crucible at a constant, controllable, settable rate. When the pellets land in the crucible's pockets, they melt. The liquid is conveyed by capillary action to the surface of the die, where it is incorporated into the growing crystal. The hopper, which holds the sapphire feed pellets, is inside a feeder. The feeder is suspended from a load cell. As feed leaves the hopper and is dropped into the crucible, the feeder becomes lighter, which is registered by the load cell. Inside the feeder is a vibratory tray, which when vibrating, causes pellets to flow down an inclined trough and drop into tubes leading to the crucible pockets. A feedback controller turns the vibrator (attached to the vibratory tray) on and off according to the feeder weight, controlling the feed rate.

It is important that the feed rate of pellets to the crucible be quite constant, which means the feed rate fluctuates in a certain (and narrow) range over time. If the feed rate is too high, the pockets may overfill and clog. If the feed rate is too low, the pockets may run dry, compromising the growth of the crystal.

To melt the feed pellets, heating power to the pockets is in balance with the heat of fusion of the pellets entering at a given rate. If feed pellets are absent for too long (and remedial action is not taken) the pockets may overheat, causing the liquid sapphire to break down into vapor, which is then incorporated as bubbles into the growing crystal, compromising its quality. Either too many or too few pellets can upset the thermal balance of the pockets. In some embodiments, the feed rate for growing sapphire crystal may be 5-15 grams/minute. The feeder is configured to maintain this rate (or another programmed rate) closely.

Because the feed rate is based on the total weight of the feeder, there is no cumulative error in the total amount of pellets fed, no matter how long the feeder runs. The only error is due to the drift of the load cell. A high-quality load cell, kept at a constant temperature, is quite stable. In one embodiment, a flexible shroud may be placed around the load cell to protect it from air currents, which can affect its reading.

Even very small amounts of air or water will compromise the quality of the crystal being formed. The feed pellets tend to adsorb water and air on their surface. This surface layer preferably should be baked off under a vacuum (described below) and replaced by hydrogen. After the hopper (inside the feeder) is loaded with clean feed, the feeder is then vacuumed down to a pressure of 25-50 μ (microns of mercury) using a vacuum pump or equivalent component(s) to remove any trace of air or water, then backfilled with high-purity hydrogen through a port in the feeder and a hydrogen source. A constant flow of clean, dry hydrogen via the hydrogen port purges the feeder at all times to cleanse it of air or water which may diffuse in. A computer controller may be used to control this operation using valves and device actuation.

In one embodiment, a bottom of the feeder may include a Y-connector, which may divide the stream of pellets (falling from the end of the vibratory tray) into two equal streams, one for each pocket in the crucible. The position of the connector is controlled by one or more X-Y screw positioners. This allows for very precise adjustment of the flow(s) of the feed particles to equalize the flows between the two feed tubes. The one or more X-Y screw positioners may then be locked in position once the optimal configuration of the X-Y screw positioner(s) is reached. The Y-connector may also allow only one of the two feed tubes to be used instead of both. In some embodiments, the top of the Y-connector may be sealed to the bottom of the feeder. In some embodiments, each fork of the bottom of the Y-connector may be sealed to a flexible feed tube. The bottom of the feed tube may be sealed to a windowed connector. The bottom of the windowed connector may be sealed to an alumina feed tube, the bottom of which may be inserted into a tungsten feed-tube cap. The feed-tube cap may rest on the tungsten feed tube, which may rest on the pocket cover, which may cover the pocket. Thus, the pellets may be guided from the end of the vibratory trough inside the feeder directly into the crucible pocket. A tungsten scatter pin across the inside of the tungsten feed tube may distribute the falling pellets evenly over the surface area of the pocket, eliminating potential hot spots. Alternatively, other materials known in the art may also be used for the above-discussed components without straying from the scope of this invention as long as they can withstand operational conditions and perform the above-discussed functions.

The windowed connector connecting the flexible feed tube to the alumina feed tube may allow visual access to the pocket. Using a camera and monitor system, the melting of the feed pellets may be confirmed, and the level of liquid sapphire precisely determined. Adjustments to the feed rate and temperature of the pockets are made based on this visual access. These adjustments can be performed by either a human operator or a computerized feedback loop.

Alumina is a desirable material for the feed tube because alumina is impermeable to air or moisture. Alumina can also withstand the high temperature at the top of the tungsten feed tube. It is also non-contaminating to the sapphire growth process.

Since the feed rate is controlled by the weight of the hopper, preferably, the hopper may hang freely so its weight can be measured precisely. In such embodiments, it is preferable that the hopper is not connected to another part of the system by a rigid element, so that the rigid element may provide support to the hopper, introducing errors in the measurement of the hopper's weight. This requires that the feed tubes to the crucible be flexible, which presents a new technological challenge, as discussed below.

No flexible material is adequately impermeable to air and moisture for use as a feed tube. Therefore, in some embodiments, the feed tubes may be made of double-walled polyurethane tubing, with hydrogen flowing through the interstice. In some embodiments, the inner tube may be made of polyurethane, which is clear, non-contaminating, and cannot be chipped by sapphire pellets. The outer tube may be made of Polyvinyl Chloride (PVC), which is clear and very flexible. This arrangement allows flexible feed tubes to be used, which are essential for accurately measuring the weight of the feeder, and adequately protects the feed pellets from moisture and air which diffuse through the outer flexible tube, where moisture and air may be swept away by the flowing hydrogen gas.

Water and air, even in very small quantities, compromise the clarity of the grown sapphire crystal. Both of these substances may accumulate on the surface of sapphire feed pellets and must be removed before usage. Before loading the pellets into the feeder, they may be treated in a baking box. The feed pellets may be baked at ˜300° F. under a 25-50 μ vacuum (drawn by a vacuum pump or equivalent), and backfilled with hydrogen through a port and hydrogen source while still hot. The vacuuming and backfilling may be repeated several times to ensure that all impurities diffuse out through the matrix of sapphire pellets. In certain embodiments, this may be performed as a computer-controlled system in an automated and monitored fashion with sensors tracking pressure, temperature, time, and other parameters.

The treated feed pellets may be cooled under hydrogen and then, may get loaded into the feeder. The loading step may be implemented by transporting the contents of the baking box through a flexible, non-contaminating tube connecting the baking box to the feeder. In preferred embodiments, the tube may be thoroughly purged of air and have hydrogen (through a port and from a hydrogen source) flowing through it, while the feed pellets are transported through the tube. After loading the cleaned feed pellets in the feeder, the feeder may be pumped down to 25-50 μ using a vacuum pump which may be the same or different from the vacuum pump of the baking box, then backfilled with hydrogen. It may be continuously purged of air with hydrogen to sweep away gaseous impurities that may diffuse into the atmosphere.

In some embodiments, a hydrogen-argon mixture may be used instead of hydrogen in the presently disclosed system. The benefit of this is that, unlike hydrogen, the mixture may be non-flammable.

### BRIEF DESCRIPTION OF THE DRAWINGS

The present disclosure is further illustrated by way of exemplary embodiments, which are described in detail through the accompanying drawings. These embodiments are not limiting, and in these embodiments, the same numbering indicates the same structure, wherein:

FIG. 1 is a front-view diagram of a sapphire pellet feed system for the growth of sapphire crystals, according to some embodiments of the present disclosure;

FIG. 2 is a side-view diagram of the sapphire pellet feed system for the growth of sapphire crystals, according to some embodiments of the present disclosure;

FIG. 3 is a detail side-view diagram of a feeder of the sapphire pellet feed system for the growth of sapphire crystals, according to some embodiments of the present disclosure;

FIG. 4 is a detail front-view diagram of a Y-connector of the sapphire pellet feed system for the growth of sapphire crystals, according to some embodiments of the present disclosure;

FIG. 5 is a detail front-view diagram of a windowed connector of the sapphire pellet feed system for the growth of sapphire crystals, according to some embodiments of the present disclosure;

FIG. 6 is a detail front-view diagram of a crucible of the sapphire pellet feed system for the growth of sapphire crystals, and the surrounding structures, according to some embodiments of the present disclosure;

FIG. 7 is a flow diagram illustrating a method of growing sapphire crystals using a sapphire pellet feed system, according to some embodiments of the present disclosure;

FIG. 8 is a structural diagram illustrating a baking box system used for the pre-processing of the sapphire pellets in the method of growing sapphire crystals using a sapphire pellet feed system, according to some embodiments of the present disclosure.

### DETAILED DESCRIPTION

In order to more clearly illustrate the technical solutions of the embodiments of the present disclosure, the accompanying drawings for the description of the embodiments are described below. Obviously, the accompanying drawings in the following description are only some examples or embodiments of the present disclosure, and it is possible for a person of ordinary skill in the art to apply the present disclosure to other similar scenarios in accordance with these accompanying drawings without creative labor. Unless obviously obtained from the context or the context illustrates otherwise, the same numeral in the drawings refers to the same structure or operation.

It should be understood that the terms “system,” “device,” “unit,” and/or “module” are used herein as a way to distinguish between different components, elements, parts, sections, or assemblies at different levels. However, if other words may achieve the same purpose, the terms may be replaced with alternative expressions.

As indicated in the present disclosure and in the claims, unless the context clearly suggests an exception, the words “one,” “a,” “a kind of,” and/or “the” do not refer specifically to the singular but may also include the plural. In general, the terms “include” and “comprise” suggest only the inclusion of clearly identified steps and elements, which do not constitute an exclusive list, and the method or device may also include other steps or elements.

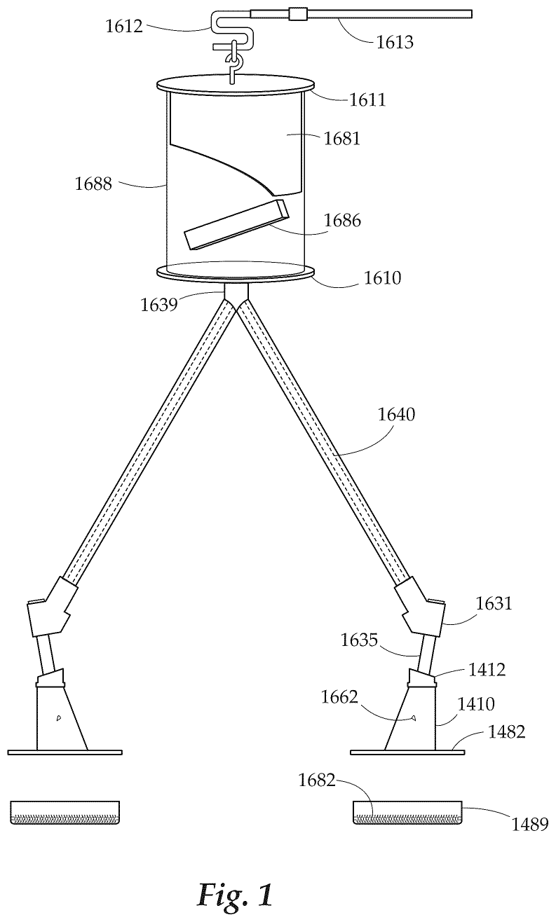

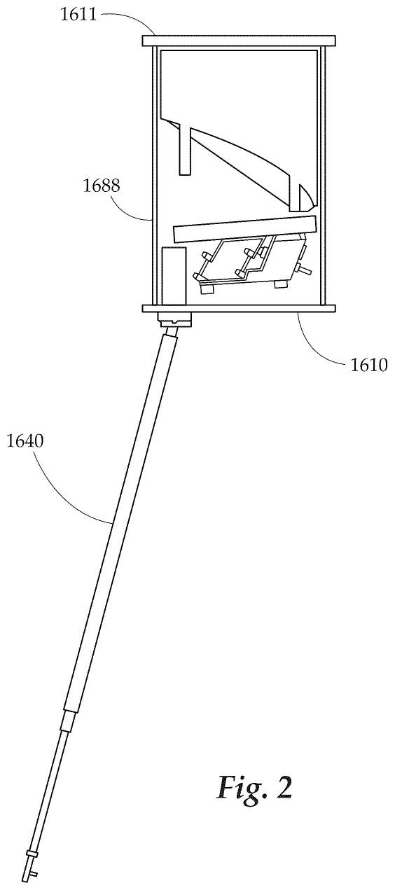

FIG. 1 is a front-view diagram of a sapphire pellet feed system for the growth of sapphire crystals, according to some embodiments of the present disclosure. FIG. 2 is a side-view diagram thereof.

In some embodiments, the sapphire pellet feed system may include a feeder 1688 suspended from a load cell 1612. Alternatively, the feeder 1688 may be supported by the load cell 1612. In some embodiments, the load cell 1612 may be the only structure supporting the feeder 1688 so that the weight of the feeder may be accurately measured by the load cell. In some embodiments, the load cell 1612 may be a strain gauge load cell, a capacitive load cell, a piezoelectric load cell, or a tension/compression load cell. In some embodiments, a flexible shroud may be placed around the load cell 1612 to protect it from air currents, which might introduce errors to its reading. In some embodiments, the load cell 1612 may output an electronic signal reflecting its measurement through its connecting wires 1613. The electronic signal may be transferred to a feedback controller, which may be implemented on one or more computerized devices, for further processing.

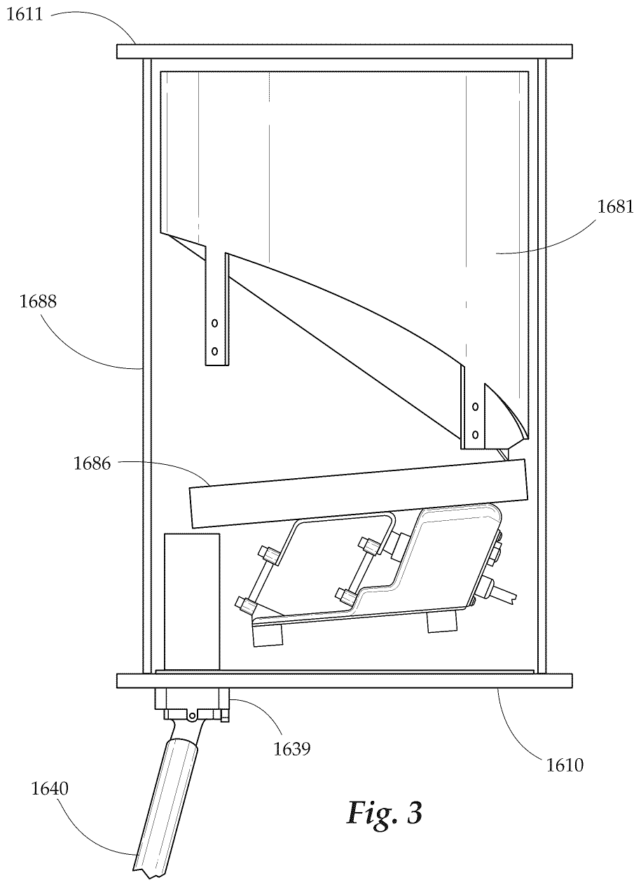

FIG. 3 is a detail side-view diagram of the feeder 1688, according to some embodiments of the present disclosure.

In some embodiments, the feeder 1688 may be cylindrical, but the feeder can also be of other shapes. As in FIG. 3, in some embodiments, the feeder 1688 may have a body with a top plate 1611 and a bottom plate 1610. In some embodiments, the top plate 1611 and the bottom plate 1610 may be detachable. In some embodiments, the feeder 1688 may house a feed hopper 1681. In some embodiments, the feed hopper 1681 may be shaped as a cylindrical wedge and placed on the upper half of the feeder 1688. The feed hopper 1681 may store and dispense feed pellets. In some embodiments, the feeder 1688 may also house a vibrator 1686, which may be placed under the feed hopper 1681. In some embodiments, the vibrator 1686 may be an Erie Z model A vibrator. In some embodiments, the vibrator 1686 may move the feed pellet as a continuous stream into the Y-connector 1639, which may be placed at the bottom of the feeder 1688 and will be discussed in detail in the later sections. In some embodiments, the vibrator 1686 may include an inclined trough. In some embodiments, when the vibrator 1686 operates, it may cause feed pellets to slide down along the inclined trough and enter the Y-connector 1639. In some embodiments, the feedback controller may turn the vibrator 1686 on/off based on the measurement of the load cell 1612. In some embodiments, the feedback controller may also adjust the power of the vibrator 1686. Hence, the dispensing rate of the feed pellets, which may be controlled by the vibrator 1686, may be adjusted according to the weight of the feeder 1688. In some embodiments, the vibrator 1686 may be replaced by other components used to dispense the feed pellets, such as an agitator, an air jet, a screw feeder, or an electromagnetic feeder. These components may also be controlled by the feedback controller to adjust the dispensing rate of the feed pellets based on the weight of the feeder 1688.

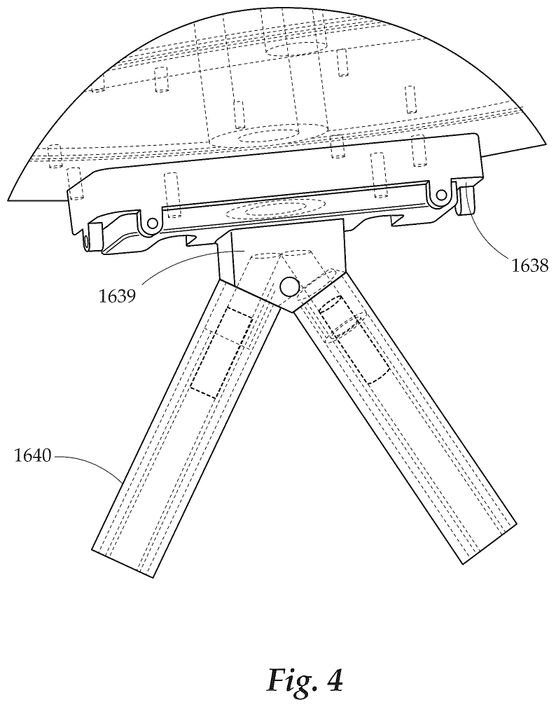

FIG. 4 is a detail front-view diagram of the Y-connector 1639, according to some embodiments of the present disclosure.

In some embodiments, a bottom of the feeder 1688 may include a Y-connector 1639, which may divide the stream of feed pellets into two equal sub-streams, one for each crucible. In some embodiments, the Y-connector 1639 may be replaced by a multi-way connector, so that the stream of feed pellets may be divided into more than two equal sub-streams, corresponding to more than two crucibles. In some embodiments, the Y-connector 1639 may be replaced by a straight connector, so that the stream of feed pellets may be directed to a single crucible. In some embodiments, the Y-connector 1639 may not necessarily divide the stream of feed pellets into equal sub-streams, for two crucibles of different sizes, or crystals of different target sizes.

In some embodiments, the Y-connector 1639 may include one or more X-Y screw positioners 1638, which allow precise adjustment of the Y-connector's location, thus ensuring an even distribution of the feed pellets between both branches of the Y-connector 1639. The one or more X-Y screw positioners 1638 may be locked in position once the Y-connector 1639's optimal position has been reached. The one or more X-Y screw positioners 1638 may either be adjusted manually or automatically. The one or more X-Y positioners 1638 may also be controlled by the feedback controller. In some embodiments, the one or more X-Y screw positioners 1638 may be replaced by other components performing the same function, such as linear actuators, gimbal mounts, or tiny robotic arms. In some embodiments, the top of the Y-connector 1638 may be sealed to the bottom of the feeder 1688. In some embodiments, the one or more X-Y screw positioners 1638 may be placed under the bottom plate 1610.

In some embodiments, each fork of the bottom of the Y-connector 1638 may be sealed to a flexible feed tube 1640. As discussed above, to make sure that the measurement of the load cell 1612 accurately reflects the weight of the feeder 1688, the feed tubes 1640 may need to be flexible to ensure that they do not provide extra support for the feeder. In some embodiments, the feed tubes 1640 may be double-walled polyurethane tubes, with hydrogen flowing through the interstice between the walls. In some embodiments, a port in the Y-shaped connector 1639 may provide an inlet for the hydrogen to enter the space between the two walls of the feed tubes 1640. The flowing hydrogen may sweep away water vapor and air between the feed tubes 1640. Hence, this design allows flexible feed tubes to be used while adequately protecting the feed pellets from moisture and air.

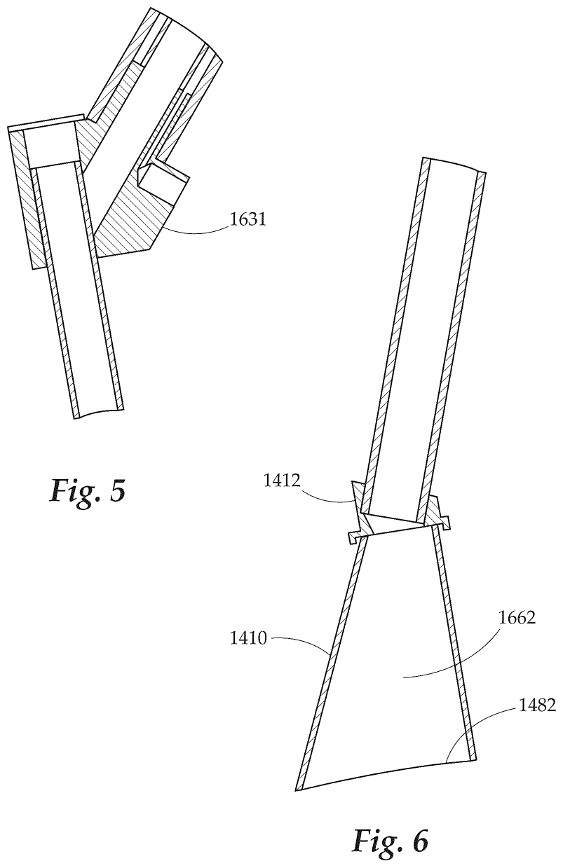

FIG. 5 is a detail front-view diagram of a windowed connector 1631, according to some embodiments of the present disclosure. In some embodiments, the windowed connector 1631 may be placed at the end of the feed tubes 1640. The window on the connector 1631 may allow visual access to the pocket 1489. An operator or an automated camera may perform the observation, to monitor the state of the melting feed pellets in the pocket 1489, which will be discussed in detail. Data gathered from the observation may be entered or transferred to the feedback controller, based on which the feed rate of the feed pellets and the temperature of the pocket 1489 may be adjusted.

FIG. 6 is a detail front-view diagram of a feed tube and the surrounding structures, according to some embodiments of the present disclosure.

In some embodiments, a bottom of the windowed connector 1631 may connect to a rigid feed tube 1635. In some embodiments, the rigid feed tube 1635 may be made of alumina. In some embodiments, the rigid feed tube 1635 may be made of other materials that are inflexible and resistant to moisture, air, and heat, and are non-contaminating to the process. In some embodiments, the bottom of the rigid feed tube 1635 may connect to a cap 1412. In some embodiments, the cap 1412 may be made of tungsten. In some embodiments, the bottom of the rigid feed tube 1635 may be inserted into the cap 1412. In some embodiments, the cap 1412 may connect to the top of a flared feed base 1410. In some embodiments, the flared feed base 1410 may also be made of tungsten. In some embodiments, the flared feed base 1410 may have one or more scatter pins 1602, to ensure an even distribution of feed pellets, thus eliminating potential hotspots. The flare feed base 1410 may rest on a pocket cover 1482, which may cover a crucible pocket 1489. The feed pellets may be heated and melted in the crucible pocket 1489. The crucible pocket 1489 may be heated by a heater, which may be a resistance heater, an induction heater, a furnace, a gas burner, etc. In some embodiments, the temperature of melting feed pellets in the crucible pocket 1489 may be measured by a temperature probe and recorded by the feedback controller. The feedback controller may in turn adjust the operation of the heater. The crucible pocket 1489 may include a heating fin 1682 to enhance the transfer of heat.

In some embodiments, the rigid feed tube 1635, the cap 1412, and the flare feed base 1410 may be replaced by one or more other types of connecting parts, as long as they allow the feed pellets to travel through and reach the crucible pocket 1489, and observation of the crucible pocket from the windowed connector 1631. Wherein, the one or more connecting parts may be rigid to allow such observation.

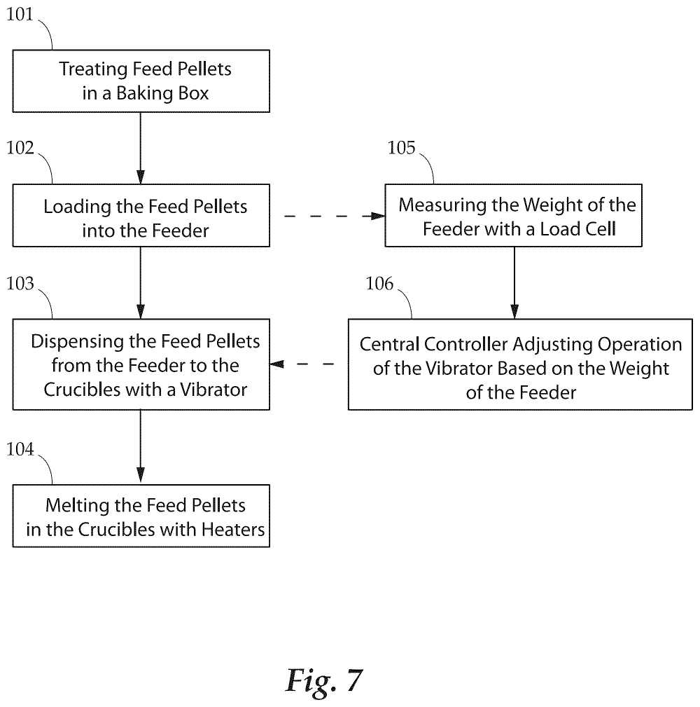

FIG. 7 is a flow diagram illustrating a method of growing sapphire crystals using a sapphire pellet feed system, according to some embodiments of the present disclosure.

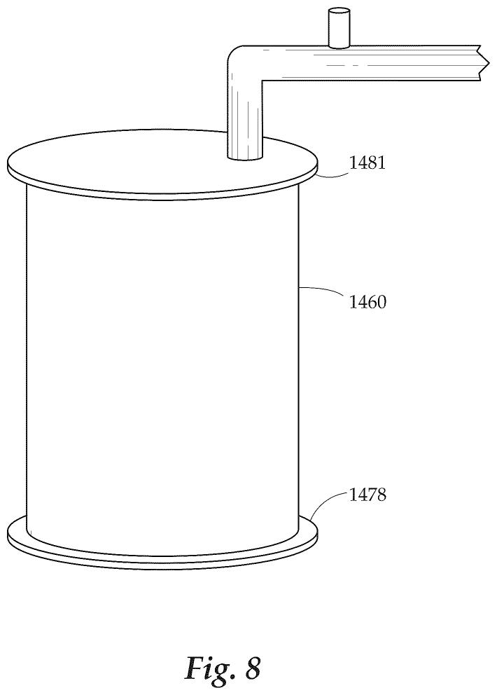

At 101, the feed pellets are treated in a baking box 1460, whose structure is illustrated in FIG. 8.

Water and air, even in very small quantities, can comprise the clarity of sapphire crystal produced by the crystal growing processes. Both of these substances may accumulate on the surface of sapphire feed pellets and must be removed before usage. Hence, the feed pellets may need to be degassed in a baking box before they are used, to remove the residue water and air on their surfaces. As shown in FIG. 8, the baking box 1460 may have a top cover plate 1481, and a bottom plate 1478, which may serve as a base and sealing structure for the baking box.

The feed pellets may be baked at ˜300° F. under a 25-50 μ vacuum in the baking box 1460. The top cover plate 1481 may include inlet(s) through which hydrogen may be fed into the baking box 1460, and from which vacuum may be drawn. After the feed pellets are baked, the baking box 1460 may be backfilled with hydrogen when the content of the box is still hot. The vacuuming and backfilling may be repeated several times to ensure that all impurities are removed. In some embodiments, the box may include sensors measuring the temperature, pressure, oxygen content, hydrogen content, etc. Data collected by the sensors may be sent to the feedback controller. In some embodiments, the feedback controller may make adjustments to the baking process accordingly, such as adjusting the heat, vacuum, length of time, and other parameters of the baking process.

At 102, the feed pellets are loaded into the feeder 1688.

Before the feed pellets are loaded into the feeder 1688, treated feed pellets may be cooled under hydrogen. In some embodiments, the contents of the baking box may be transported to the feeder 1688 through a flexible, non-contaminating tube. In some embodiments, the tube may be thoroughly purged of air and have hydrogen flowing through it while the feed pellets are transported through the tube. In some embodiments, the hydrogen may enter through an inlet on the tube and from a hydrogen source. After loading the cleaned feed pellets in the feeder 1688, the feeder may be pumped down to 25-50 μ using a vacuum pump and then backfilled with hydrogen. The feeder 1688 may be continuously purged of air with hydrogen to sweep away gaseous impurities. In some embodiments, the feed pellets may be transported to a hopper 1681, housed in the feeder 1688.

At 103, the feed pellets may be dispensed to the crucibles. As discussed above, in some embodiments, the rate of dispensing the feed pellets may be adjusted by turning on/off a vibrator 1686 housed in the feeder 1688 or adjusting the power of the vibrator. As discussed above, the feed pellets may travel through a plurality of connecting parts, including a Y-connector 1639, a flexible feed tube 1640, a windowed connector 1631, an alumina feed tube 1635, a cap 1412, and a flared feed base 1410 before reaching the crucible.

At 104, the feed pellets in the crucibles may be melted by a heater.

At 105, the weight of the feeder 1688 may be measured by a load cell 1612. As discussed above, the load cell 1612 may be the only structure the feeder 1688 is suspended from or supported by, and there may not be other rigid structures supporting the feeder, so that the measurement of the load cell 1612 may accurately reflect the weight of the feeder 1688. The measurement of the load cell 1612 may be transferred to a feedback controller in real time. As discussed above, in some embodiments, other data regarding the presently disclosed method may also be transferred to and processed by the feedback controller. These data may be collected by cameras and/or sensors placed in the system.

At 106, the feedback controller may make adjustments to the operation of the vibrator 1686 based on the measurement of the load cell 1612 (and sometimes also other data such as an input setpoint). In some embodiments, as discussed above, other parameters of the presently disclosed system, such as the power of the heaters, the dispensing rate of the hydrogen source(s), etc., may also be adjusted by the feedback controller. In some embodiments, decisions made by the feedback controller may be manually overridden.

Furthermore, unless explicitly stated in the claims, the use of order, numbers, letters, or other names for processing elements and sequences are not intended to limit the order of the processes and methods of the present disclosure. While various examples have been discussed in the disclosure as currently considered useful embodiments of the invention, it should be understood that such details are provided for illustrative purposes only. The appended claims are not limited to the disclosed embodiments, and instead, the claims are intended to cover all modifications and equivalent combinations within the scope and essence of the embodiments disclosed in the present disclosure. For example, although the described system components may be implemented through a hardware device, they may also be realized solely through a software solution, such as installing the described system on an existing processing or mobile device.

Similarly, it should be noted that, for the sake of simplifying the presentation of embodiments disclosed in the present disclosure and aiding in understanding one or more embodiments of the present disclosure, various features have been sometimes combined into a single embodiment, drawing, or description. However, this manner of disclosure does not imply that the features required by the claims are more than the features mentioned in the claims. In fact, the features of the embodiments are less than all the features of the single embodiment disclosed in the foregoing disclosure.

In some embodiments, numeric values describing the composition and quantity of attributes are used in the description. It should be understood that such numeric values used for describing embodiments may be modified with qualifying terms such as “about,” “approximately” or “generally”. Unless otherwise stated, “about,” “approximately” or “generally” indicates that a variation of ±20% is permitted in the described numbers. Accordingly, in some embodiments, the numerical parameters used in the disclosure and claims are approximations, which can change depending on the desired characteristics of the individual embodiment. In some embodiments, the numerical parameters should take into account a specified number of valid digits and employ a general manner of bit retention. Although the numerical ranges and parameters used in some embodiments of the present disclosure to confirm the breadth of the range are approximations, in specific embodiments, such numerical values are set as precisely as practicable.

With respect to each of the patents, patent applications, publications of patent applications, and other material, such as articles, books, specifications, publications, documents and the like, cited in the present disclosure, the entire contents thereof are hereby incorporated herein by reference. Application history documents that are inconsistent with the contents of the present disclosure or that create conflicts are excluded, as are documents (currently or hereafter appended to the present disclosure) that limit the broadest scope of the claims of the present disclosure. It should be noted that in the event of any inconsistency or conflict between the descriptions, definitions, and/or use of terminology in the materials appended to the present disclosure and the contents described herein, the descriptions, definitions, and/or use of terminology in the present disclosure shall prevail.

In closing, it should be understood that the embodiments described in the present disclosure are used only to illustrate the principles of the embodiments of the present disclosure. Other deformations may also fall within the scope of the present disclosure. Therefore, by way of example and not limitation, alternative configurations of the embodiments disclosed in the present disclosure may be considered consistent with the teachings of the present disclosure. Accordingly, the embodiments described in the present disclosure are not limited to the explicitly introduced and described embodiments in the present disclosure.

What is claimed is:

1. A feed system for growing crystals, comprising:
a feeder suspended from a cell load;
wherein, the cell load measures a weight of the feeder and sends the weight of the feeder to a computerized device in real time;
wherein, the feeder houses a hopper and a vibrator;
wherein, the hopper holds feed pellets;
wherein, the vibrator controls a rate of dispensing the feed pellets from the hopper;
wherein, the computerized device controls an operation of the vibrator, based on the weight of the feeder;
a Y-connector connected to a bottom of the feeder;
wherein, the Y-connector includes two side branches;
two flexible feed tubes respectively connected to the two side branches, wherein the two flexible feed tubes have two concentric layers of walls, with hydrogen flowing through an interstice between the two concentric walls;
two windowed connectors respectively connected to the two feed tubes;
two groups of rigid connecting parts connected to the windowed connectors;
wherein, the Y-connector, the two flexible feed tubes, the two windowed connectors, and the two groups of rigid connecting parts allow the feed pellets to travel through and reach two crucibles, in which the feed pellets are melted;
wherein, the two windowed connectors respectively provide visual access to the two crucibles.

2. The feed system in claim 1, wherein the Y-connector divides the feed pellets into two equal streams.

3. The feed system in claim 2, wherein the Y-connector includes one or more X-Y screw positioners, allowing precise adjustments of a location of the Y-connector.

4. The feed system in claim 1, wherein the Y-connector includes an inlet for the hydrogen.

5. The feed system in claim 1, wherein each group of the two groups of the rigid connecting parts includes a rigid feed tube, a cap, and a flared feed base.

6. The feed system in claim 5, wherein the flared feed base includes one or more scatter pins.

7. The feed system in claim 5, wherein the flared feed base rests on a pocket cover, which covers the crucible.

8. The feed system in claim 1, wherein the two crucibles include heating fins.

9. The feed system in claim 1, wherein the feed pellets are baked in a baking box before entering the feeder.

10. The feed system in claim 9, wherein the feed pellets are baked at 300° F. under a 25-50 μ vacuum.

11. A method of feeding pellets to crucibles for growing crystals, comprising:
loading feed pellets into a feeder;
wherein, the feeder houses a hopper and a vibrator;
wherein, the hopper holds the feed pellets;
wherein, the vibrator controls a rate of dispensing the feed pellets from the hopper;
dispensing the feed pellets to two crucibles;
wherein, the feed pellets travel though:
a Y-connector connected to a bottom of the feeder;
wherein, the Y-connector includes two side branches;
two flexible feed tubes respectively connected to the two side branches, wherein the two flexible feed tubes have two concentric walls, with hydrogen flowing through an interstice between the two concentric walls;
two windowed connectors respectively connected to the two feed tubes;
two groups of rigid connecting parts connected to the windowed connectors;
melting the feed pellets in the two crucibles;
measuring a weight of the feeder using a load cell in real time;
wherein the feeder is suspended from the load cell;
sending the weight of the feeder to a computerized device in real time;
adjusting, by the computerized device, an operation of the vibrator, based on the weight of the feeder.

12. The method in claim 11, wherein the Y-connector divides the feed pellets into two equal streams.

13. The method in claim 12, wherein the Y-connector includes one or more X-Y screw positioners, allowing precise adjustments of a location of the Y-connector.

14. The method in claim 11, wherein the Y-connector includes an inlet for the hydrogen.

15. The method in claim 11, wherein each group of the two groups of the rigid connecting parts includes a rigid feed tube, a cap, and a flared feed base.

16. The method in claim 15, wherein the flared feed base includes one or more scatter pins.

17. The method in claim 15, wherein the flared feed base rests on a pocket cover, which covers the crucible.

18. The method in claim 11, wherein the two crucibles include heating fins.

19. The method in claim 11, further comprising:
baking the feed pellets in a baking box.

20. The method in claim 19, wherein the baking of the feed pellets is at 300° F. under a 25-50 μ vacuum.
